(19) United States
(12) Patent Application Publication
(10) Pub. No.: US 2026/0092361 A1
(43) Pub. Date: Apr. 2, 2026

(54) CLEANING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventors: Yoma YAMANE, Toyama-shi (JP); Kiyohisa ISHIBASHI, Toyama-shi (JP); Shingo NOHARA, Toyama-shi (JP)

(73) Assignee: Kokusai Electric Corporation, Tokyo (JP)

(21) Appl. No.: 19/328,560

(22) Filed: Sep. 15, 2025

(30) Foreign Application Priority Data
Sep. 27, 2024 (JP) 2024-169442

(51) Int. Cl. C23C 16/44; C23C 16/455; H01L 21/67

(52) U.S. Cl. CPC C23C 16/4405; C23C 16/4408; C23C 16/45563; H10P 72/0402

(57) ABSTRACT

It is possible to suppress a deviation in an etching amount in a process chamber. There is provided a technique that includes: (a) supplying a first gas into a process chamber from one or more first positions in a first direction; and (b) supplying a second gas into the process chamber from one or more second positions in the first direction different from the one or more first positions, wherein the process chamber is configured to be capable of accommodating a substrate along a plane perpendicular to the first direction, the first gas is one of a cleaning gas and an additive gas reacting with the cleaning gas, and the second gas is the other one of the cleaning gas and the additive gas.

### CROSS-REFERENCE TO RELATED PATENT APPLICATION

This non-provisional U.S. patent application is based on and claims priority under 35 U.S.C. § 119 of Japanese Patent Application No. 2024-169442, filed on Sep. 27, 2024, in the Japanese Patent Office, the entire contents of which are hereby incorporated by reference.

### BACKGROUND

### 1. Field

The present disclosure relates to a cleaning method, a method of manufacturing a semiconductor device, a non-transitory computer-readable recording medium and a substrate processing apparatus.

### 2. Related Art

According to some related arts, as a part of a manufacturing process of a semiconductor device, a step of cleaning (or etching) an inside of a process chamber (in which a process gas is supplied to a substrate) with a cleaning gas may be performed.

### SUMMARY

According to the present disclosure, there is provided a technique capable of suppressing a deviation in an etching amount in a process chamber.

According to an embodiment of the present disclosure, there is provided a technique that includes: (a) supplying a first gas into a process chamber from one or more first positions in a first direction; and (b) supplying a second gas into the process chamber from one or more second positions in the first direction different from the one or more first positions, wherein the process chamber is configured to be capable of accommodating a substrate along a plane perpendicular to the first direction, the first gas is one of a cleaning gas and an additive gas reacting with the cleaning gas, and the second gas is the other one of the cleaning gas and the additive gas.

### BRIEF DESCRIPTION OF THE DRAWINGS

FIG. 1 is a diagram schematically illustrating a configuration of a substrate processing apparatus used in one or more embodiments of the present disclosure.

FIG. 2 is a diagram schematically illustrating a horizontal cross-section of the substrate processing apparatus used in the embodiments of the present disclosure.

FIG. 3 is a block diagram schematically illustrating a configuration of a controller and its related components of the substrate processing apparatus used in the embodiments of the present disclosure.

FIG. 4 is a timing chart schematically illustrating a first cleaning step according to the embodiments of the present disclosure.

FIG. 5 is a timing chart schematically illustrating a second cleaning step according to the embodiments of the present disclosure.

FIG. 6 is a timing chart schematically illustrating a modified example of the first cleaning step according to the embodiments of the present disclosure.

FIG. 7 is a timing chart schematically illustrating a modified example of the second cleaning step according to the embodiments of the present disclosure.

### DETAILED DESCRIPTION

### Embodiments of Present Disclosure

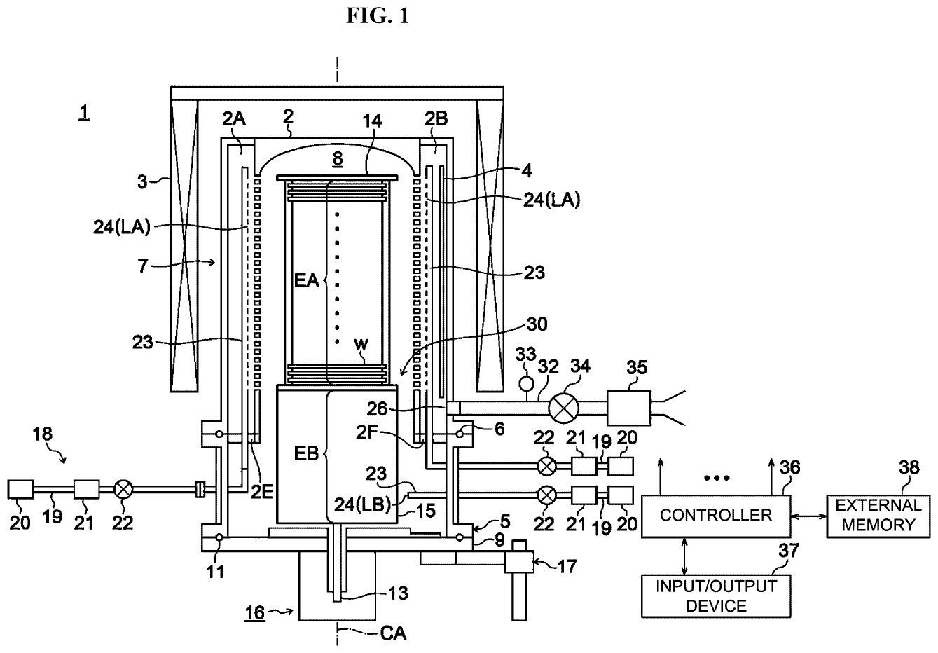

Hereinafter, one or more embodiments (hereinafter, also simply referred to as “embodiments”) according to the present disclosure will be described with reference to FIGS. 1 to 7. For example, the drawings used in the following descriptions are all schematic, and a relationship between dimensions of each component and a ratio of each component shown in the drawing may not always match the actual ones. In addition, even between the drawings, the relationship between the dimensions of each component and the ratio of each component may not always match.

### Configuration of Substrate Processing Apparatus

FIG. 1 is a diagram schematically illustrating a configuration of a substrate processing apparatus 1. As shown in FIG. 1, the substrate processing apparatus 1 includes a reaction tube 2 serving as a reaction vessel and a heater 3 serving as a temperature regulator (which is a temperature adjusting structure). The reaction tube 2 is of a cylindrical shape, and is constituted by a ceiling configured to close an upper end thereof and an opening configured to open a lower end thereof. For example, the reaction tube 2 is made of a heat resistant material such as quartz (SiO₂) and silicon carbide (SiC). The heater 3 is of a cylindrical shape. The heater 3 is supported by a support plate (not shown) such that the heater 3 can be installed vertically and provided in a manner concentric with the reaction tube 2. The heater 3 also functions as an activator (also referred to as an “exciter”) capable of activating (or exciting) a gas by a heat.

A temperature detector 4 is installed inside the reaction tube 2. In an example shown in FIG. 1, the temperature detector 4 is installed upright along an inner wall of the reaction tube 2.

A manifold 5 is arranged at a bottom of the reaction tube 2. A process vessel 7 is constituted mainly by the reaction tube 2 and the manifold 5. The manifold 5 is of a cylindrical shape with open upper and lower ends. A seal cap 9 serving as a lid is provided below the manifold 5. The seal cap 9 is configured to be capable of airtightly sealing (closing) a lower end opening of the manifold 5. In other words, the lower end of the manifold 5 is closed by the seal cap 9 of a disk shape.

The lower end of the reaction tube 2 and the manifold 5 are connected via a seal 6 such as an O-ring. The manifold 5 supports the lower end of the reaction tube 2. The reaction tube 2 is installed vertically, similar to the heater 3. In such a state, the seal cap 9 closes a lower end opening of the process vessel 7. For example, the manifold 5 is made of a metal material such as stainless steel (SUS).

A process chamber 8 is provided inside the process vessel 7. In the process chamber 8, a plurality of wafers W can be accommodated. Hereinafter, each of the plurality of wafers W may also be referred to as a “wafer W” which serves as a substrate. The wafer W is processed in the process chamber 8. That is, a processing of the wafer W is performed in the process chamber 8. In the process vessel 7 according to the present embodiments, a “direction of a central axis CA” serving as a first direction is used as a vertical direction. The direction of the central axis CA also serves as the first direction of the process chamber 8.

A state of electric conduction to the heater 3 is adjusted based on temperature information detected by the temperature detector 4. As a result, a desired temperature distribution of a temperature (inner temperature) of the process chamber 8 can be obtained.

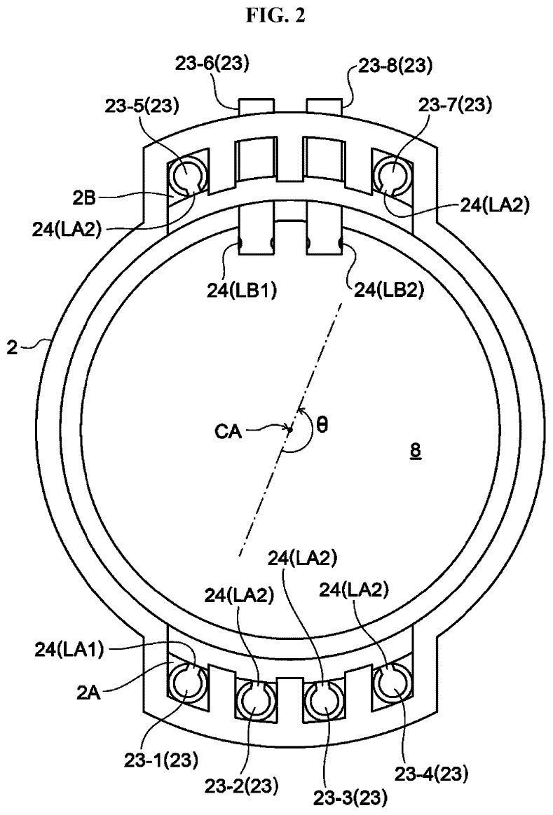

FIG. 2 is a diagram schematically illustrating a horizontal cross-section of the substrate processing apparatus 1. As shown in FIG. 2, the reaction tube 2 is provided with a first buffer chamber 2A and a second buffer chamber 2B. The first buffer chamber 2A and the second buffer chamber 2B are provided to face each other and protrude outward (in a radial direction) from the reaction tube 2. Each of the first buffer chamber 2A and the second buffer chamber 2B is partitioned into a plurality of spaces by partition walls extending vertically. According to the present embodiments, each of the first buffer chamber 2A and the second buffer chamber 2B is partitioned into four parts (spaces).

Boundary walls among the first buffer chamber 2A, the second buffer chamber 2B and the process chamber 8 are located where the first buffer chamber 2A and the second buffer chamber 2B are not provided. A cross-section of each boundary wall is of an arc shape, and an inner diameter of each boundary wall is set to be the same (substantially the same) as an inner diameter of the reaction tube 2. As a result, a structure in which a periphery of the wafer W is surrounded by a wall provided in a manner concentric with the wafer W can be provided. Each boundary wall is provided with a plurality of slits configured to communicate between the process chamber 8 and the first buffer chamber 2A or the second buffer chamber 2B.

Nozzles 23-1, 23-2, 23-3 and 23-4 serving as first nozzles are installed in each partition of the first buffer chamber 2A. Nozzles 23-5 and 23-7 serving as the first nozzles are also arranged in partitions at both ends of the four partitions of the second buffer chamber 2B. Hereinafter, each of the first nozzles may also be referred to as a “first nozzle”. Gases can be supplied toward the vicinity of the wafer W accommodated in the process chamber 8 through the nozzles 23-1, 23-2, 23-3, 23-4, 23-5 and 23-7.

The nozzles 23-1, 23-2, 23-3, 23-4, 23-5 and 23-7 extend in the first direction, that is, an up-down direction (vertical direction), in the reaction tube 2 along the inner wall of the reaction tube 2. It may also be said that the nozzles 23-1, 23-2, 23-3, 23-4, 23-5 and 23-7 are installed upright in parallel to the central axis CA. The nozzle 23 may also be referred to as a “long nozzle”. The nozzle 23 is provided with a plurality of supply holes 24 (LA) serving as first supply holes provided in the first direction. Hereinafter, each of the supply holes 24 (LA) may also be referred to as a “supply hole 24 (LA)”. When the wafer W is accommodated (or held) in a boat 14, the supply hole 24 (LA) is open toward the wafer W. A predetermined process gas (which is selected) is supplied into the process chamber 8 through the supply hole 24 (LA).

An opening 2E is provided below the first buffer chamber 2A. The nozzles 23-1, 23-2, 23-3 and 23-4 are inserted into the opening 2E. An opening 2F is provided below the second buffer chamber 2B. The nozzles 23-5 and 23-7 are inserted into the opening 2F.

A width of the opening 2E is set to be substantially the same as a width of the first buffer chamber 2A. A width of the opening 2F is set to be substantially the same as a width of the second buffer chamber 2B.

Nozzles 23-6 and 23-8 serving as second nozzles are arranged below the second buffer chamber 2B. Each of the nozzles 23-6 and 23-8 is configured as a short tube extending horizontally from the manifold 5. Each of the nozzles 23-6 and 23-8 may also be referred to as a “short nozzle”.

Two supply holes 24 (LB) are provided at locations of the nozzles 23-6 and 23-8 near front ends (tips) thereof. Hereinafter, each of the two supply holes 24 (LB) may also be referred to as a “supply hole 24 (LB)”. As shown in FIG. 2, the supply holes 24 (LB) of the nozzles 23-6 and 23-8 are open toward a circumferential direction of the reaction tube 2.

In the following, the nozzles 23-1 to 23-8 may be collectively or individually referred to as “nozzles 23” or “nozzle 23”. In FIG. 1, positions of components such as the nozzles 23 and an exhaust pipe 32 are merely shown for convenience of illustration.

For example, the nozzle 23 is made of a heat resistant material such as quartz or SiC. Gas supply pipes 19 are connected to the nozzles 23, respectively. Hereinafter, each of the gas supply pipes 19 may be collectively or individually referred to as a “gas supply pipe 19”.

As shown in FIG. 1, the boat 14 serving as a substrate support structure is accommodated in the process chamber 8. The boat 14 is configured to support (hold or accommodate) the plurality of wafers W (for example, from 25 wafers to 150 wafers W) arranged at a predetermined interval therebetween such that the wafers W are supported in a shelf-like manner while stacked in the direction of the central axis CA and provided along planes perpendicular to the central axis CA (that is, along a horizontal direction in the present embodiments). The process chamber 8 is configured to accommodate the boat 14 capable of supporting the wafers W in the process chamber 8. For example, the boat 14 is made of a heat resistant material such as quartz and SiC.

A heat insulating structure 15 serving as a heat insulator is disposed below the boat 14. The boat 14 is supported by the heat insulating structure 15. A substrate support 30 is constituted by the boat 14 and the heat insulating structure 15. The substrate support 30 is capable of supporting the wafers W. In the process vessel 7, a substrate placement region (substrate placement area) EA and a substrate non-placement region (substrate non-placement area) EB are provided. The substrate placement region EA includes a region where the wafer W is placed. The substrate non-placement region EB is located below the substrate placement region EA. The substrate non-placement region EB includes a region surrounded by the manifold 5. The substrate non-placement region EB is a region where the wafer W is not placed.

An outer shape of the heat insulating structure 15 is cylindrical. The heat insulating structure 15 is supported by a rotating shaft 13 penetrating through the seal cap 9. A center line of the rotating shaft 13 coincides with the central axis CA of the reaction tube 2. The rotating shaft 13 is connected to a rotator (which is a rotating structure) 16 installed on a lower surface of the seal cap 9. For example, a magnetic fluid seal is provided at a portion of the rotating shaft 13, where the rotating shaft 13 penetrates through the seal cap 9. The rotating shaft 13 is configured to be capable of being rotated while airtightly (or hermetically) sealing an inside (inner portion) of the reaction tube 2. When the rotating shaft 13 is rotated, the heat insulating structure 15 and the boat 14 are rotated together.

The seal cap 9 is driven in the up-down direction by a boat elevator 17 serving as an elevating structure. The boat elevator 17 is configured to elevate and lower the substrate support 30. By elevating or lowering the substrate support 30, the boat 14 is transferred (loaded) into or transferred (unloaded) out of the inside of the reaction tube 2 through the opening of the reaction tube 2. That is, the reaction tube 2 accommodates the boat 14 such that the boat 14 can be loaded and unloaded through the opening of the reaction tube 2. The seal cap 9 is configured to close the lower end opening of the manifold 5 such that the boat 14 can be loaded or unloaded.

The substrate processing apparatus 1 is provided with a gas supply structure 18 serving as a first gas supply system (also referred to as a “first gas supplier”) or a second gas supply system (also referred to as a “second gas supplier”). The gas supply structure 18 includes the gas supply pipe 19, a mass flow controller (MFC) 21 and a valve 22 serving as an opening/closing valve. The gas supply structure 18 is configured to supply the gas such as a source gas, a reactive gas, an inert gas, a cleaning gas and an additive gas (which serves as process gases used in a substrate processing described later) into the process chamber 8. Hereinafter, each of the process gases may also be referred to as the “process gas”. The process gas supplied by the gas supply structure 18 is selected in accordance with a type of a film to be formed and a type of the gas used in a cleaning process described later.

One or both of the source gas and the reactive gas may also be referred to as a “film forming gas”, and one or both of a source gas supply system (also referred to as a “source gas supplier”) and a reactive gas supply system (also referred to as a “reactive gas supplier”) may also be referred to as a “film forming gas supply system” (also referred to as a “film forming gas supplier”) which is a film forming gas supply line.

According to the present embodiments, the gas supply structure 18 includes the source gas supplier, the reactive gas supplier, an inert gas supplier (which is an inert gas supply system), a purge gas supplier (which is a purge gas supply system), a cleaning gas supplier (which is a cleaning gas supply system) and an additive gas supplier (which is an additive gas supply system). For example, each of the gas suppliers mentioned above is constituted by at least one nozzle among the nozzles 23-1 to 23-8. In the following, when the gas suppliers mentioned above are described in a collective manner rather than individually, the gas suppliers will be described as a “gas supplier 20” which is a representative example thereof. It may be considered that the gas supply structure 18 includes the gas supplier 20. The gas supply pipe 19 is connected to the gas supplier 20. The mass flow controller (MFC) 21 serving as a flow rate controller (flow rate control structure) and the valve 22 serving as the opening/closing valve are sequentially provided at the gas supply pipe 19 in this order from an upstream side to a downstream side of the gas supply pipe 19 in a gas flow direction. Each of the nozzles 23 penetrates a side wall of the manifold 5. A downstream end of the gas supply pipe 19 is connected to the nozzle 23.

The process gas (which is desired) can be selectively supplied to the nozzle 23 or the nozzles 23 by the gas supplier 20 through the upstream side of the gas supply pipe 19. The gas supply pipe 19, the MFC 21 and the valve 22 may be configured as an integrated gas supply system in which such components are integrated. The integrated gas supply system is configured such that an opening and closing operation of the valve 22 and a flow rate adjusting operation by the MFC 21 are controlled by a controller 36 serving as a control structure described later.

Positions of the supply holes 24 (LA) provided in the nozzles 23-1, 23-2, 23-3, 23-4, 23-5 and 23-7 may also be referred to as “first positions LA”. Hereinafter, each of the first positions LA may also be referred to as a “first position LA”. The first position LA is a position of the substrate placement region EA in the first direction.

Positions of the supply holes 24 (LB) provided in the nozzles 23-6 and 23-8 may also be referred to as “second positions LB”. Hereinafter, each of the second positions LB may also be referred to as a “second position LB”. The second position LB is a position of the substrate non-placement region EB in the first direction. The second position LB is a position below the boat 14 (that is, the substrate support structure) in the first direction.

The second position LB is different from the first position LA in the first direction. The second position LB is closer to a lower end of the process chamber 8 than the first position. In addition, the first position LA is located where the boat 14 serving as the substrate support structure is provided in the first direction, and the second position LB is at a location where the heat insulating structure 15 serving as the heat insulator is provided in the first direction. It can be said that the second position LB is located where the substrate support structure is not provided in the first direction.

As shown in the FIG. 2, the nozzles 23-6 and 23-8 are provided at different positions in a circumferential direction of the process chamber 8. Therefore, the positions of the supply holes 24 (LB) provided in the nozzles 23-6 and 23-8 are also different in the circumferential direction of the process chamber 8. It can be said that the position of the supply hole 24 (LB) provided in the nozzle 23-6 is a (2-1)^{th} position (which refers to a primary second position) LB1, and the position of the supply hole 24 (LB) provided in the nozzle 23-8 is a (2-2)^{th} position (which refers to a secondary second position) LB2. Thus, the second positions LB include the (2-1)^{th} position LB1 and the (2-2)^{th} position LB2, which are different in the circumferential direction of the process chamber 8.

Similarly, as shown in FIG. 2, the nozzles 23-1, 23-2, 23-3, 23-4, 23-5 and 23-7 are provided at different positions in the circumferential direction of the process chamber 8. Therefore, the positions of the supply holes 24 (LA) provided in the nozzles 23-1, 23-2, 23-3, 23-4, 23-5 and 23-7 are also different from one another in the circumferential direction of the process chamber 8, as shown in FIG. 2. Specifically, when the position of the supply hole 24 (LA) provided in one of the nozzles 23-1, 23-2, 23-3, 23-4, 23-5 and 23-7 is a (1-1)^{th} position (which refers to a primary first position) LA1, it can be said that the position of the supply hole 24 (LA) provided in each of the other nozzles 23 is a (1-2)^{th} position (which refers to a secondary first position) LA2. In FIG. 2, the position of the supply hole 24 (LA) provided in the nozzle 23-1 is illustrated as the (1-1)^{th} position LA1. In such a case, the position of the supply hole 24 (LA) provided in the nozzles 23-2, 23-3, 23-4, 23-5 and 23-7 is the (1-2)^{th} position LA2. That is, the first positions LA (which are the positions of the supply holes 24 (LA) provided in the nozzles 23-1, 23-2, 23-3, 23-4, 23-5 and 23-7) include the (1-1)^{th} position LA1 and the (1-2)^{th} position LA2 which is different from the (1-1)^{th} position LA1 in the circumferential direction of the process chamber 8.

As shown in FIG. 2, when viewed in the first direction, the nozzle 23-1 and the nozzle 23-7 are located at positions facing each other (that is, opposite to each other) via the central axis CA. Similarly, when viewed in the first direction, the nozzle 23-2 and the nozzle 23-8 are also located at positions facing each other via the central axis CA. In addition, the nozzle 23-3 and the nozzle 23-6 are also located at positions facing each other via the central axis CA. In addition, the nozzle 23-4 and the nozzle 23-5 are located at positions facing each other via the central axis CA. In other words, the nozzle 23-1 and the nozzle 23-7 are located at the positions facing each other via a center of the process chamber 8 when viewed from above. The nozzles 23-2 and 23-8 are also located at the positions facing each other, the nozzles 23-3 and 23-6 are also located at the positions facing each other and the nozzles 23-4 and 23-5 are also located at the positions facing each other, via the center of the process chamber 8 when viewed from above the process chamber 8.

In addition, the term “positions facing each other” includes not only a case where the nozzles related thereto are located at positions in which a central angle therebetween is 180 degrees around the central axis CA but also a case where the nozzles related thereto are located at positions in which a central angle therebetween is in a predetermined angle range including 180 degrees. For example, the predetermined angle range may refer to a case shown in FIG. 2 where a nozzle for a specific nozzle 23 is located where an angle θ along a counterclockwise direction from the specific nozzle 23 is within a range from 120 degrees to 240 degrees when viewed from above the process chamber 8. In FIG. 1, an example of the angle θ in the counterclockwise direction from the nozzle 23-1 is shown.

From such a viewpoint, for example, the nozzle 23-8 is also located at the position facing the nozzle 23-1. Similarly, the nozzle 23-6 and the nozzle 23-7 are also located at the positions facing the nozzle 23-2. In addition, the nozzle 23-5 and the nozzle 23-8 are also located at the positions facing the nozzle 23-3. In addition, the nozzle 23-6 is also located at the position facing the nozzle 23-4. The range of the angle θ is preferably 140 degrees or more and 220 degrees or less, more preferably 160 degrees or more and 200 degrees or less. In other words, the narrower the range of the angle θ, the closer the two target nozzles 23 are located at the “positions facing each other”, to face each other in a direction closer to parallel.

In addition, a relationship between the nozzles 23 located at the “positions facing each other” is relative for each of the nozzles 23 that satisfies the relationship. For example, the nozzles 23-4 and 23-3 are located at the positions facing the nozzle 23-5. The nozzles 23-3 and 23-4 are located at the positions facing the nozzle 23-6. The nozzles 23-1 and 23-2 are located at the positions facing the nozzle 23-7. The nozzles 23-2 and 23-1 are located at the positions facing the nozzle 23-8.

As shown in FIG. 1, an exhaust port 26 is provided in an outer wall of the second buffer chamber 2B in the partition where the nozzle 23 is not arranged. Exhaust openings (exhaust slits) through which the gas is exhausted from the process chamber 8 is constituted by a plurality of slits provided in the boundary wall between the process chamber 8 and the partition of the second buffer chamber 2B where the nozzle 23 is not arranged. The exhaust pipe 32 is attached to the exhaust port 26. The exhaust pipe 32 is connected to a vacuum pump 35 serving as a vacuum exhaust apparatus via a pressure sensor 33 serving as a pressure detector (pressure detection structure) and an APC (Automatic Pressure Controller) valve 34 serving as a pressure regulator (pressure adjustment structure). The pressure sensor 33 is configured to detect a pressure (inner pressure) of the process chamber 8. With such a configuration, it is possible to adjust the inner pressure of the process chamber 8 to a pressure appropriate for the processing of the wafer W.

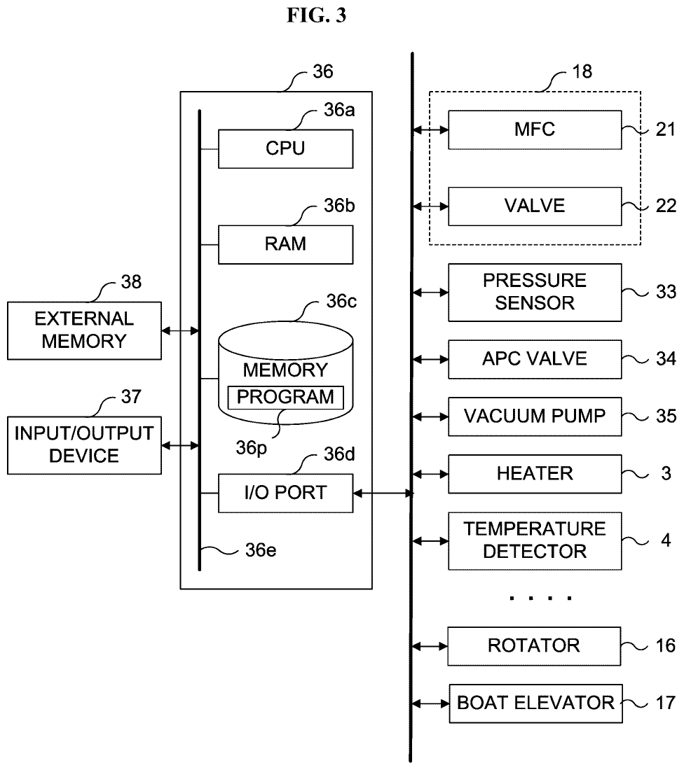

As shown in FIG. 3, the controller 36 serving as the control structure is connected to the rotator 16, the boat elevator 17, the MFC 21 and the valve 22 of the gas supply structure 18 and the APC valve 34 to control such components. The controller 36 serving as the control structure is constituted by a computer including a CPU (Central Processing Unit) 36a, a RAM (Random Access Memory) 36b, a memory 36c and an I/O port (input/output port) 36d. The RAM 36b, the memory 36c and the I/O port 36d are configured to be capable of changing data with the CPU 36a through an internal bus 36e. For example, an input/output device 37 constituted by a component such as a touch panel and an external memory 38 configured to store various data are connected to the controller 36.

For example, the memory 36c is configured by a component such as a flash memory, a hard disk drive (HDD) and a solid state drive (SSD). For example, a control program configured to control an operation of the substrate processing apparatus 1 and a program 36p such as a process recipe containing information on procedures and conditions of the substrate processing described later may be readably stored in the memory 36c. The process recipe is obtained by combining steps (procedures) of the substrate processing described later such that the controller 36 can execute the steps to acquire a predetermined result, and functions as a program. Hereinafter, the process recipe and the control program may be collectively or individually referred to as a “program” or a “program product”. In addition, the process recipe may also be simply referred to as a “recipe”. Thus, in the present specification, the term “program” may refer to the recipe alone, may refer to the control program alone or may refer to both of the recipe and the control program. The RAM 36b functions as a memory area (work area) where a program or data read by the CPU 36a is temporarily stored.

The I/O port 36d is connected to the components described above such as the MFC 21, the valve 22, the pressure sensor 33, the APC valve 34, the vacuum pump 35, the temperature detector 4, the heater 3, the rotator 16 and the boat elevator 17.

The CPU 36a is configured to read the control program from the memory 36c and execute the control program read from the memory 36c. In addition, the CPU 36a is also configured to read the recipe from the memory 36c, for example, in accordance with an operation command inputted from the input/output device 37. In accordance with contents of the recipe read from the memory 36c, the CPU 36a is configured to be capable of controlling various operations such as the flow rate adjusting operation for various gases by the MFC 21, the opening and closing operation of the valve 22, an opening and closing operation of the APC valve 34, a pressure regulating operation (pressure adjusting operation) by the APC valve 34, a start and stop operation of the vacuum pump 35, a temperature regulating operation (temperature adjusting operation) by the heater 3 based on the temperature detector 4, an operation of adjusting a rotation and a rotation speed of the boat 14 by the rotator 16 and an elevating and lowering operation of the boat 14 by the boat elevator 17.

The controller 36 may be embodied by installing the above-described program stored in the external memory 38 into the computer. For example, the external memory 38 may include a magnetic disk such as the HDD, an optical disk such as a CD and a semiconductor memory such as a USB memory and the SSD. The memory 36c or the external memory 38 may be embodied by a non-transitory computer readable recording medium. Hereafter, the memory 36c and the external memory 38 may be collectively or individually referred to as a “recording medium”. Thus, in the present specification, the term “recording medium” may refer to the memory 36c alone, may refer to the external memory 38 alone, or may refer to both of the memory 36c and the external memory 38. Instead of the external memory 38, a communication interface such as the Internet and a dedicated line may be used for providing the program to the computer.

Subsequently, a process (film forming process) of forming a film on the wafer W using the substrate processing apparatus 1 mentioned above will be described. The present embodiments will be described by way of an example in which a silicon nitride (SiN) film is formed on the wafer W by supplying a silicon (Si)-containing gas serving as the source gas and a nitrogen (N)-containing gas serving as the reactive gas to the wafer W. In addition, in the following description, operations of components constituting the substrate processing apparatus 1 are controlled by the controller 36.

### Wafer Charging Step and Boat Loading Step

When the plurality of wafers W are loaded (charged) into the boat 14 (wafer charging step), the boat 14 is transferred (loaded) into the process chamber 8 by the boat elevator 17 (boat loading step). As a result, a lower portion of the reaction tube 2 and therebelow are airtightly closed (sealed) by the seal cap 9.

### Pressure Adjusting Step and Temperature Adjusting Step

The process chamber 8 is vacuum-exhausted (decompressed and exhausted) by the vacuum pump 35 such that the inner pressure of the process chamber 8 reaches and is maintained at a predetermined pressure (vacuum degree). The APC valve 34 is feedback-controlled based on pressure information measured by the pressure sensor 33 (pressure adjusting step). In addition, the heater 3 heats the process chamber 8 such that a temperature of the wafer W in the process chamber 8 reaches and is maintained at a desired process temperature (temperature adjusting step). In addition, the rotator 16 starts rotating the boat 14 and the wafer W.

In the present step, for example, the manifold 5 is heated by a heater element (not shown) to a set temperature between 200° C. and 300° C. For example, the set temperature may be set such that a partial pressure of by-products does not exceed a saturated vapor pressure at the set temperature. The by-products are not limited to one type, and may include a substance such as ammonium chloride and chlorosilane polymer, and silicon deposited on surfaces other than the wafer W. In addition, the heater element continuously heats the manifold 5 at least until the film forming process is completed.

### Film Forming Process: S64

As the film forming process, the following four steps are performed.

### Source Gas Supply Step

When the inner temperature of the process chamber 8 is stabilized at a pre-set temperature, the source gas is supplied to the wafer W in the process chamber 8 through the gas supplier 20. After a flow rate of the source gas is controlled by the MFC 21 to a desired flow rate, the source gas whose flow rate is controlled is supplied into the process chamber 8 through the gas supply pipe 19 and the nozzle 23.

### Source Gas Exhaust Step

Subsequently, a supply of the source gas is stopped, and the process chamber 8 is vacuum-exhausted by the vacuum pump 35. In the present step, the APC valve 34 is temporarily fully opened. Thereby, the exhaust port 26 may be heated by the gas of a high temperature flowing into the exhaust port 26 at a large flow rate.

### Reactive Gas Supply Step

Subsequently, the reactive gas is supplied to the wafer W in the process chamber 8. After a flow rate of the reactive gas is controlled by the MFC 21 to a desired flow rate, the reactive gas whose flow rate is controlled is supplied into the process chamber 8 through the gas supply pipe 19 and the nozzle 23. For example, the reactive gas is supplied through the nozzle 23 different from the nozzle 23 through which the source gas is supplied.

### Reactive Gas Exhaust Step

Subsequently, a supply of the reactive gas is stopped, and the process chamber 8 is vacuum-exhausted by the vacuum pump 35.

By performing a cycle of performing the four steps mentioned above a predetermined number of times (one or more times), it is possible to form, on the wafer W, a silicon nitride film of a predetermined composition and a predetermined thickness.

### Boat Unloading Step and Wafer Discharging Step

After the film of the predetermined thickness is formed, the inert gas is supplied through the gas supplier 20, the inner atmosphere of the process chamber 8 is replaced with the inert gas, and the inner pressure of the process chamber 8 is returned to a normal pressure (atmospheric pressure). Thereafter, the seal cap 9 is lowered by the boat elevator 17, and the boat 14 is transferred (unloaded) from the reaction tube 2 (boat unloading step). Thereafter, the wafers W which are processed are removed from the boat 14 (wafer discharging step).

For example, temperature conditions (that is, the temperature of the wafer W) when forming the silicon nitride film on the wafer W are within a range from 300° C. to 700° C. In the present specification, a notation of a numerical range such as “from 300° C. to 700 °C” means that a lower limit and an upper limit thereof are included in the numerical range. Therefore, for example, the numerical range “from 300° C. to 700 °C” means a range equal to or higher than 300° C. and equal to or lower than 700° C. The same also applies to other numerical ranges described herein. In addition, the film forming process is not limited to a case of forming the silicon nitride film on the wafer W. For example, the film forming process may also be suitably applied to a case of forming a film such as a silicon oxide (SiO₂) film and a silicon oxynitride (SiON) film on the wafer W.

As the silicon-containing gas serving as the source gas, for example, a gas containing silicon and halogen, that is, a halosilane gas may be used. As the halosilane gas, for example, a chlorosilane gas such as monochlorosilane (SiH₃Cl) gas, dichlorosilane (SiH₂Cl₂) gas, trichlorosilane (SiHCl₃) gas, tetrachlorosilane (SiCl₄) gas and hexachlorodisilane (Si₂Cl₆) gas may be used. For example, one or more of the gases exemplified above as the chlorosilane gas may be used as the source gas.

As the nitrogen-containing gas serving as the reactive gas, for example, a hydrogen nitride gas such as ammonia (NH₃) gas, diazene (N₂H₂) gas and hydrazine (N₂H₄) gas may be used. For example, one or more of the gases exemplified above as the hydrogen nitride gas may be used as the reactive gas.

As the inert gas, for example, nitrogen (N₂) gas or a rare gas such as argon (Ar) gas, helium (He) gas, neon (Ne) gas and xenon (Xe) gas may be used. For example, one or more of the gases exemplified above as the inert gas may be used as the inert gas. The same also applies to each step described later.

### Cleaning Process

Subsequently, the cleaning process of cleaning an inside (inner portion) of the process chamber 8 is performed. When the film forming process mentioned above is performed, a deposit (deposition film) including the film formed by a reaction of a film forming agent (that is, the source gas and the reactive gas) and the by-products generated in the film forming process may be formed on surfaces of components (structures) facing the inside of the process chamber 8, such as the inner wall of the reaction tube 2, an inner wall of the manifold 5, a surface of the heat insulating structure 15 and a surface of the boat 14. Such a deposition film may be accumulated by repeatedly performing the film forming process mentioned above, and gradually become thicker. When the deposition film is accumulated, for example, the deposition film may peel off and be attached to the wafer W in a subsequent execution of the film forming process. As a result, foreign matters may be generated in the film forming process. Therefore, in preparation for the subsequent execution of the film forming process, the deposition film is removed from the process chamber 8 when a thickness of the deposition film reaches a predetermined thickness. Properties (such as a composition and a thickness) of the deposit and the like may differ between an inside of the nozzle, an inside of a furnace (that is, the reaction tube 2) and a furnace opening (that is, the manifold 5), and generally, the deposit and the like tend to adhere particularly in a large amount to the inside (inner portion) of the nozzle 23 through which the source gas is supplied and to a low temperature portion on an opening portion of the nozzle 23. In addition, the deposit and the like are more likely to adhere to a low temperature region in the process chamber 8 (that is, a region which is not surrounded by the heater 3 and does not horizontally surround a wafer arrangement region) than a high temperature region in the process chamber 8 (that is, a region surrounded by the heater 3 and horizontally surrounding the wafer arrangement region).

In the cleaning process described below, the cleaning gas and the additive gas reacting with the cleaning gas are used. As the cleaning gas, for example, a gas containing a halogen element (such as fluorine (F), chlorine (Cl), bromine (Br) and iodine (I)) may be used. As the gas containing the halogen element, for example, a fluorine (F)-containing gas such as fluorine (F₂) gas, hydrogen fluoride (HF) gas, nitrogen trifluoride (NF₃) gas and chlorine trifluoride (ClF₃) gas may be used. In addition, as the gas containing the halogen element, for example, a chlorine (Cl)-containing gas such as chlorine (Cl₂) gas, hydrogen chloride (HCl) gas and chlorine trifluoride (ClF₃) gas may be used. For example, one or more of the gases exemplified above may be used as the cleaning gas.

In addition, as the additive gas, for example, a gas such as hydrogen (H₂) gas, oxygen (O₂) gas, nitrous oxide (N₂) gas, nitric oxide (NO) gas, isopropyl alcohol ((CH₃)₂CHOH) gas, methanol (CH₃OH) gas, water vapor, nitrogen dioxide (NO₂) gas and the HF gas may be used. For example, one or more of the gases exemplified above may be used as the additive gas.

A halogen-containing gas may be used as the cleaning gas, and a gas free of the halogen element may be used as the additive gas. In addition, a first halogen-containing gas may be used as the cleaning gas, and a second halogen-containing gas may be used as the additive gas. For example, when the HF gas is used as the additive gas, it is preferable that one or more of gases (other than the HF gas) such as the F₂ gas, the ClF₃ gas, the NF₃ gas and a mixture thereof may be used as the cleaning gas.

### Boat Loading Step

An empty boat 14 (that, is, the boat 14 in a state where the wafer W is not accommodated therein) is loaded into the process chamber 8 using substantially the same procedure as that of loading the boat 14 in the film forming process.

### Pressure Adjusting Step and Temperature Adjusting Step

The process chamber 8 is vacuum-exhausted by the vacuum pump 35 such that the inner pressure of the process chamber 8 reaches and is maintained at a desired pressure (vacuum degree). The vacuum pump 35 continuously operates at least until a purge of a residual cleaning gas in the process chamber 8 is completed. When the process chamber 8 is vacuum-exhausted, the inert gas serving as the purge gas is supplied through the gas supply pipe 19. For example, the inert gas may be continuously supplied until the cleaning process is completed.

The state of electric conduction to the heater 3 is controlled such that the inner temperature of the process chamber 8 reaches and is maintained at a first temperature (T1) (which is predetermined), and the inner temperature of the process chamber 8 is lowered. For example, the first temperature (T1) is within a range from 200° C. to 400° C. In addition, a heating by the heater 3 and a cooling by a cooling structure are controlled such that a temperature of the furnace opening reaches and is maintained at a second temperature (T2) (which is predetermined). Such a temperature control is continuously performed at least until a cleaning of the inside of the process chamber 8 is completed. It is preferable that the range of the first temperature and a range of the second temperature are separated by 100° C. or more at least at temperature measurement points, and do not overlap with each other.

Subsequently, the rotator 16 rotates the boat 14. The rotator 16 continuously rotates the boat 14 at least until the cleaning of the inside of the process chamber 8 is completed. Alternatively, the boat 14 may not be rotated.

### First Cleaning Step

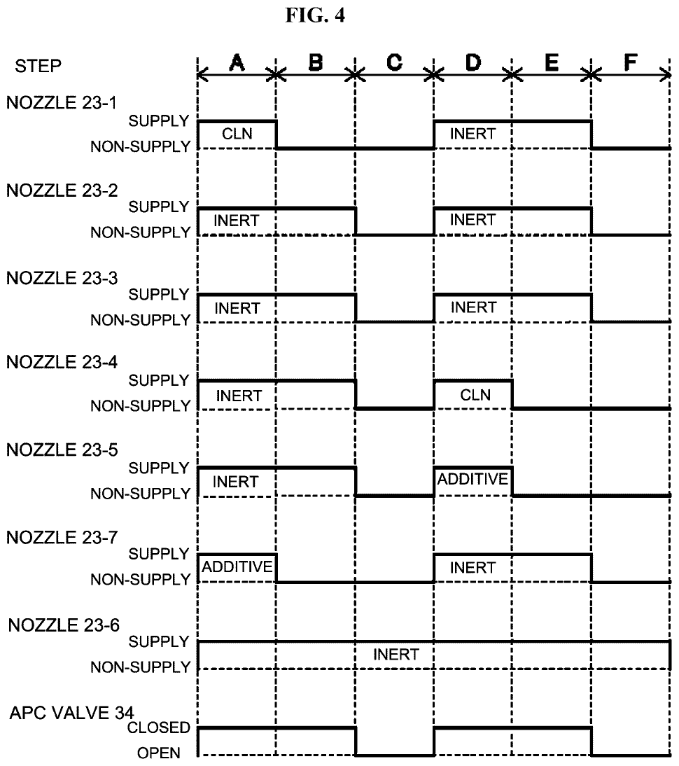

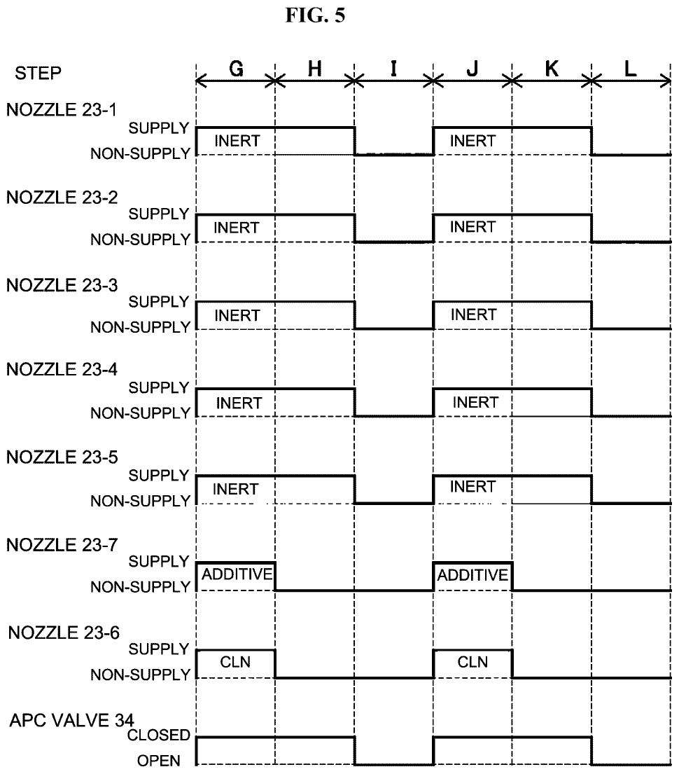

Then, a first cleaning step is performed. In the first cleaning step, (a) a step of supplying a first gas (which is one of the cleaning gas and the additive gas) into the process chamber 8 from a first position in an inner circumferential direction of the process chamber 8 and (b) a step of supplying a second gas (which is the other one of the cleaning gas and the additive gas) into the process chamber 8 from a second position different from the first position in the inner circumferential direction of the process chamber 8. Specifically, in the first cleaning step, a cycle is constituted by a step A, a step B, a step C, a step D, a step E and a step F described below, and such a cycle is performed a predetermined number of times (one or more times) in accordance with a timing chart shown in FIG. 4. In addition, in FIG. 4, notations “CLN”, “ADDITIVE” and “INERT” refer to the cleaning gas, the additive gas and the inert gas, respectively. The same also applies to FIGS. 5 to 7.

In the step A, the APC valve 34 is closed. Then, the cleaning gas serving as the first gas is supplied into the process chamber 8 through the nozzle 23-1. In addition, the additive gas serving as the second gas is supplied into the process chamber 8 through the nozzle 23-7. Further, the inert gas is supplied into the process chamber 8 through the nozzles 23-2, 23-3, 23-4, 23-5 and 23-6. For example, the present embodiments will be described by way of an example in which the cleaning gas is used as the first gas and the additive gas is used as the second gas. However, the additive gas may be used as the first gas and the cleaning gas may be used as the second gas. For example, the present embodiments will be described by way of a case where an exhaust of the process chamber 8 is completely stopped with the APC valve 34 closed. However, the present embodiments may include a case where the exhaust of the process chamber 8 is performed continuously but slightly, for example, to adjust the inner pressure of the process chamber 8.

In the step A, the process chamber 8 is in a state where the cleaning gas and the additive gas are present. Since the cleaning gas reacts with the additive gas in the process chamber 8, it is possible to generate, in the process chamber 8, active species containing the halogen element (that is, halogen-containing active species) such as a halogen element radical and a compound containing an activated halogen element. In the process chamber 8, a mixed gas generated by adding the halogen-containing active species to the cleaning gas is present. The mixed gas comes into contact with the deposit in the process chamber 8. Thereby, it is possible to remove the deposit attached to the inside of the process chamber 8 by a thermochemical reaction (that is, an etching reaction) between the mixed gas and the deposit. The halogen-containing active species acts to promote the etching reaction by the cleaning gas, thereby increasing an etching rate of the deposit, that is, assisting an etching. For example, when the fluorine-containing gas is used as the cleaning gas and a gas containing nitrogen (N) and oxygen (O) is used as the additive gas, it is possible to generate the halogen-containing active species such as a fluorine radical (F*) and nitrosyl fluoride (FNO) in the process chamber 8 by such a reaction.

The nozzle 23-1 through which the cleaning gas is supplied and the nozzle 23-7 through which the additive gas is supplied are both long nozzles. The supply hole 24 (LA) of the long nozzle is located in the substrate placement region EA, which is the first position LA. Therefore, the etching reaction mentioned above proceeds in the process chamber 8 mainly in the substrate placement region EA with a local deviation suppressed. However, the etching reaction mentioned above may also proceed in the substrate non-placement region EB with the local deviation suppressed.

After a predetermined time (for example 30 seconds) has elapsed, in the step B, a supply of the cleaning gas through the nozzle 23-1 is stopped and a supply of the additive gas through the nozzle 23-7 is also stopped. The inert gas is continuously supplied into the process chamber 8 through the nozzles 23-2, 23-3, 23-4, 23-5 and 23-6. As a result, the etching reaction mentioned above by the mixed gas proceeds in the process chamber 8. That is, the deposit attached to the inside of the process chamber 8 is further removed. Even in such a case, the etching reaction mainly proceeds in the substrate placement region EA in the process chamber 8.

In the step C, the inert gas is continuously supplied into the process chamber 8 through the nozzle 23-6, but a supply of the inert gas through the other nozzles 23 is stopped. Then, the APC valve 34 is opened. As a result, the gas containing the by-products generated by the reaction of the deposit with the cleaning gas, the cleaning gas and the additive gas which did not react with the deposit, particles generated by the etching and the like (hereinafter, the gas containing such substances may also be simply referred to as an “exhaust gas”) is exhausted from inside the process chamber 8 to an outside (outer portion) of the process chamber 8 through the exhaust pipe 32.

In the step D, the APC valve 34 is closed. Then, the cleaning gas serving as the first gas is supplied into the process chamber 8 through the nozzle 23-4. In addition, the additive gas serving as the second gas is supplied into the process chamber 8 through the nozzle 23-5. Further, the inert gas is supplied into the process chamber 8 through the nozzles 23-1, 23-2, 23-3 and 23-7. In addition, the inert gas is continuously supplied into the process chamber 8 through the nozzle 23-6.

The process chamber 8 is again in a state where the cleaning gas and the additive gas are present. Similar to the step A, a mixed gas is generated in the process chamber 8 by adding the halogen-containing active species to the cleaning gas. As a result, it is possible to remove the deposit attached to the inside of the process chamber 8 by the thermochemical reaction generated by the mixed gas.

In the step E, the supply of the cleaning gas through the nozzle 23-4 is stopped, and the supply of the additive gas through the nozzle 23-5 is also stopped. The inert gas is continuously supplied into the process chamber 8 through the nozzles 23-1, 23-2, 23-3, 23-6 and 23-7. As a result, the etching reaction proceeds in the process chamber 8 in the same manner as in the step B, and the deposit attached to the inside of the process chamber 8 is further removed.

In the step F, the inert gas is continuously supplied into the process chamber 8 through the nozzle 23-6, but the supply of the inert gas through the other nozzles 23 is stopped. Then, the APC valve 34 is opened. As a result, the exhaust gas is exhausted to the outside of the process chamber 8 through the exhaust pipe 32 in the same manner as in the step C.

For example, process conditions in the steps A and D are as follows:
A supply flow rate of the cleaning gas: from 0.5 slm to 10 slm;
A supply flow rate of the additive gas: from 0.5 slm to 10 slm;
A supply flow rate of the inert gas: from 0.01 slm to 20 slm, preferably from 0.01 slm to 10 slm;
A supply time (time duration) of supplying each gas: from 10 seconds to 300 seconds, preferably from 20 seconds to 120 seconds; and
A process pressure: from 1,330 Pa to 53,320 Pa, preferably from 9,000 Pa to 15,000 Pa.

In the first cleaning step, the cycle including the steps A to F mentioned above is performed a predetermined number of times, for example, about five times. Then, a second cleaning step is performed.

In addition, the first cleaning step is described by way of an example in which the gas is not supplied through the nozzle 23-8. However, in the first cleaning step, the gas may be supplied through the nozzle 23-8 in the same manner as a gas supply through the nozzle 23-6.

In addition, in the steps A and D of the first cleaning step, the additive gas serving as the second gas may be supplied into the process chamber 8 simultaneously through both the nozzles 23-5 and 23-7. However, in both of the steps A and D, by supplying the second gas only through the nozzle for the second gas that faces the other nozzle through which the first gas is supplied into the process chamber, it is possible to effectively suppress an etching damage in the process chamber 8.

In the first cleaning step according to the present embodiments, the nozzle 23-1 through which the first gas (which is one of the cleaning gas and the additive gas) is supplied and the nozzle 23-7 through which the second gas (which is the other one of the cleaning gas and the additive gas) is supplied are located at the positions facing each other via the central axis CA. Similarly, the nozzle 23-4 through which the first gas is supplied and the nozzle 23-5 through which the second gas is supplied are located at the positions facing each other via the central axis CA. Therefore, by supplying the first gas and the second gas into the process chamber 8 from the positions separated in a direction perpendicular to the first direction (that is, the horizontal direction), the first gas and the second gas are diffused in the horizontal direction and then mixed to generate the halogen-containing active species. In other words, it is possible to suppress deviations in a spatial concentration and a partial pressure of the halogen-containing active species capable of promoting the etching reaction, particularly in the horizontal direction, within the process chamber 8. As a result, it is possible to adjust a distribution of an etching generation rate within the process chamber 8, and it is also possible to suppress a local deviation in an amount of the etching (hereinafter, also referred to as an “etching amount”).

### Second Cleaning Step

In the second cleaning step, (a) a step of supplying the first gas (which is one of the cleaning gas and the additive gas) into the process chamber 8 from one or more first positions in the first direction and (b) a step of supplying the second gas (which is the other one of the cleaning gas and the additive gas) into the process chamber 8 from one or more second positions different from the first positions in the first direction. Specifically, in the second cleaning step, a cycle (also referred to as a “cleaning cycle”) is constituted by a step G, a step H, a step I, a step J, a step K and a step L described below, and such a cycle is performed a predetermined number of times (one or more times) in accordance with a timing chart shown in FIG. 5.

In the step G, the APC valve 34 is closed. Then, as a first gas supply step, the cleaning gas serving as the first gas is supplied into the process chamber 8 through the nozzle 23-6. In addition, as a second gas supply step, the additive gas serving as the second gas is supplied into the process chamber 8 through the nozzle 23-7. Further, the inert gas is supplied into the process chamber 8 through the nozzles 23-1, 23-2, 23-3, 23-4 and 23-5. For example, similar to the first cleaning step, the present embodiments will be described by way of an example in which the cleaning gas is used as the first gas and the additive gas is used as the second gas in the second cleaning step. However, the additive gas may be used as the first gas and the cleaning gas may be used as the second gas in the second cleaning step.

The process chamber 8 is in a state where the cleaning gas and the additive gas are present. Since the cleaning gas reacts with the additive gas in the process chamber 8, it is possible to generate the halogen-containing active species in the process chamber 8. As a result, the mixed gas is generated by adding the halogen-containing active species to the cleaning gas. The mixed gas comes into contact with the deposit in the process chamber 8. Thereby, it is possible to remove the deposit attached to the inside of the process chamber 8 by the thermochemical reaction between the mixed gas and the deposit.

In the step H, the supply of the cleaning gas through the nozzle 23-6 is stopped, and the supply of the additive gas through the nozzle 23-7 is also stopped. The inert gas is continuously supplied into the process chamber 8 through the nozzles 23-1, 23-2, 23-3, 23-4 and 23-5. As a result, the etching reaction mentioned above by the mixed gas proceeds in the process chamber 8. That is, the deposit attached to the inside of the process chamber 8 is further removed. The etching reaction in the steps G and H proceeds in the process chamber 8 in a range from the substrate non-placement region EB to the substrate placement region EA with the local deviation suppressed. In particular, by supplying the cleaning gas through the nozzle 23-6, the etching reaction proceeds more easily in the substrate non-placement region EB, that is, the lower end opening of the manifold 5, as compared with the first cleaning step. Therefore, it is possible to effectively perform the cleaning of the inside of the process chamber 8 in the substrate non-placement region EB.

In the step I, the supplies of the gases through an entirety of the nozzles 23 are stopped. Then, the APC valve 34 is opened. As a result, the exhaust gas after the deposit is removed is exhausted to the outside of the process chamber 8 through the exhaust pipe 32.

In the step J, similar to the step G, the APC valve 34 is closed. Then, the cleaning gas serving as the first gas is supplied into the process chamber 8 through the nozzle 23-6. In addition, the additive gas serving as the second gas is supplied into the process chamber 8 through the nozzle 23-7. The inert gas is supplied into the process chamber 8 through the nozzles 23-1, 23-2, 23-3, 23-4 and 23-5. Similar to the step G, the process chamber 8 is in a state where the cleaning gas and the additive gas are present, and the etching reaction occurs.

In the step K, similar to the step H, the supply of the cleaning gas through the nozzle 23-6 is stopped, and the supply of the additive gas through the nozzle 23-7 is also stopped. The inert gas is continuously supplied into the process chamber 8 through the nozzles 23-1, 23-2, 23-3, 23-4 and 23-5. The etching reaction proceeds in the process chamber 8, and the deposit attached to the inside of the process chamber 8 is further removed. Similar to the steps G and H, the etching reaction in the steps J and K proceeds in the process chamber 8 in the range from the substrate non-placement region EB to the substrate placement region EA with the local deviation suppressed. In particular, the etching reaction proceeds more easily in the substrate non-placement region EB, as compared with the first cleaning step.

In the step L, similar to the step I, the supplies of the gases through the entirety of the nozzles 23 are stopped. Then, the APC valve 34 is opened. As a result, the exhaust gas after the deposit is removed is exhausted to the outside of the process chamber 8 through the exhaust pipe 32.

For example, process conditions in the steps G and J are as follows:
A supply flow rate of the cleaning gas: from 0.5 slm to 10 slm;
A supply flow rate of the additive gas: from 0.5 slm to 10 slm;
A supply flow rate of the inert gas: from 0.01 slm to 20 slm, preferably from 0.01 slm to 10 slm;
A supply time (time duration) of supplying each gas: from 10 seconds to 300 seconds, preferably from 20 seconds to 120 seconds; and
A process pressure: from 1,330 Pa to 53,320 Pa, preferably from 9,000 Pa to 15,000 Pa.

In the second cleaning step, the cycle (that is, the cleaning cycle) including the steps G to L mentioned above is performed a predetermined number of times, for example, about 10 times.

In addition, the second cleaning step is also described by way of an example in which the gas is not supplied through the nozzle 23-8. However, in the second cleaning step, the gas may be supplied through the nozzle 23-8 in the same manner as the gas supply through the nozzle 23-6.

In addition, in the second cleaning step, the supply of the first gas through the nozzle 23-6 and the supply of the second gas through the nozzle 23-7 may be switched. That is, the cleaning gas serving as the first gas may be supplied through the nozzle 23-7, and the additive gas serving as the second gas may be supplied through the nozzle 23-6. However, in order to promote the etching in a lower portion of the process chamber 8, it is preferable that the cleaning gas is supplied through the nozzle 23-6 and the additive gas is supplied through the nozzle 23-7.

### Purge Step and Returning to Atmospheric Pressure Step

After the first cleaning step and the second cleaning step are completed, a subsequent cleaning step is performed depending on situations.

After the cleaning steps are completed, the process chamber 8 is purged. Then, the inner atmosphere of the process chamber 8 is replaced with the inert gas, and the inner pressure of the process chamber 8 is returned to the atmospheric pressure.

### Boat Unloading Step

Thereafter, the seal cap 9 is lowered by the boat elevator 17, and the lower end of the manifold 5 is opened. Then, the empty boat 14 is transferred (unloaded) through the lower end of the manifold 5 to the outside of the reaction tube 2 (boat unloading step). When a series of the steps mentioned above is completed, the substrate processing mentioned above may be performed again.

According to the second cleaning step of the present embodiments, it is possible to obtain one or more of the following effects.

The supply hole 24 (LB) of the nozzle 23-6 through which the first gas (which is one of the cleaning gas and the additive gas; and specially the cleaning gas in the embodiments mentioned above) is supplied is located in the substrate non-placement region EB (which is the second position LB). In contrast, the supply hole 24 (LA) of the nozzle 23-7 serving as the long nozzle through which the second gas (which is the other one of the cleaning gas and the additive gas; and specially the additive gas in the embodiments mentioned above) is supplied is located in the substrate placement region EA (which is the first position LA). Therefore, by supplying the first gas and the second gas respectively into the process chamber 8 from the positions separated in the first direction, the first gas and the second gas are diffused in the first direction and in the direction perpendicular to the first direction (that is, the horizontal direction) and then mixed to generate the halogen-containing active species. In other words, it is possible to suppress the deviations in the spatial concentration and the partial pressure of the halogen-containing active species capable of promoting the etching reaction within the process chamber 8. As a result, it is possible to adjust a distribution of the etching generation rate within the process chamber 8, and it is also possible to suppress the local deviation in the etching amount. In particular, it is possible to suppress the deviation in the etching amount in the direction perpendicular to the first direction.

The second position LB is lower than the first position LA in the first direction, and is particularly close to a lower end of the process vessel 7. Therefore, by supplying the cleaning gas serving as the first gas from the second position to a position close to the lower end of the process vessel 7, it is possible to promote the etching reaction at the lower end of the process vessel 7. In addition, when there is a temperature deviation between an upper portion and the lower portion of the process chamber 8, by adjusting etching conditions and a distribution of the etching amount in the up-down direction, it is possible to perform the etching appropriately. In other words, when there are regions with different temperatures in the process chamber 8, an amount of the deposition film to be etched and the etching conditions appropriate for the deposition film may be different. Specifically, for example, the etching rate is low in the substrate non-placement region EB, which tends to be a relatively low temperature region. In such a case, for example, by increasing a concentration of the first gas (particularly the cleaning gas) supplied through the nozzle 23-6 to increase the etching rate in the low temperature region, it is possible to perform the etching appropriately.

According to the present embodiments, the additive gas serving as the second gas is supplied from the first position LA, and the cleaning gas serving as the first gas is supplied from the second position LB. As a result, it is possible to promote the etching in the substrate non-placement region EB, that is, the opening close to the lower end of the process vessel 7.

The first gas supply step and the second gas supply step are performed with the substrate support 30 in the process chamber 8. When the substrate support 30 is present in the process chamber 8, it is possible to perform the cleaning process including a cleaning of the substrate support 30.

The first position LA is located where the boat 14 is provided in the process chamber 8, and the second position LB is located where the heat insulating structure 15 is provided in the process chamber 8. That is, in the second cleaning step, it is possible to promote the etching reaction particularly in the region where the heat insulating structure 15 is located in the process chamber 8, which is provided below the region where the boat 14 is located.

The first gas supply step and the second gas supply step are performed so as to overlap in time. Therefore, as compared with a case where the first gas supply step and the second gas supply step are performed without overlapping in time, it is possible to mix a sufficient amount of the first gas and the second gas in a short time. In addition, the present embodiments are not limited to a case where the first gas supply step and the second gas supply step are completely coincident in time. For example, even when the first gas supply step and the second gas supply step overlap partially, it is possible to effectively mix the first gas and the second gas during an overlapping time period of the first gas supply step and the second gas supply step.

When the first gas supply step and the second gas supply step overlap partially in time, an execution order of the first gas supply step and the second gas supply step does not matter. For example, one of the first gas supply step and the second gas supply step may be started earlier in time than the other one of the first gas supply step and the second gas supply step. Similarly, one of the first gas supply step and the second gas supply step may be ended (completed) earlier in time than the other one of the first gas supply step and the second gas supply step.

The first gas supply step and the second gas supply step are performed with the APC valve 34 closed, that is, with the exhaust of the process chamber 8 stopped. Since the first gas and the second gas supplied to the process chamber 8 remain in the process chamber 8, it is possible to effectively utilize the first gas and the second gas supplied into the process chamber 8 to promote mixing of the first gas and the second gas.

After the first gas supply step and the second gas supply step, a cycle of exhausting the gas while suspending the supply of the first gas and the supply of the second gas is performed one or more times. In other words, since an etching of the process chamber 8 and an exhaust of the gas after the etching are repeatedly performed, it is possible to exhaust a substance (such as the gas whose reactivity is reduced after the etching reaction and the by-products generated by the etching reaction) from the process chamber 8 for each cycle, and it is also possible to promote the cleaning process of the process chamber 8.

At least one among the first positions LA and at least one among the second positions LB are located at positions facing each other via the central axis CA. By supplying the gases into the process chamber 8 while the first position LA for supplying the first gas and the second position LB for supplying the second gas are located at the positions facing each other via the central axis CA, it is possible to react the first gas with the second gas with a less deviation in the process chamber 8, particularly in the direction perpendicular to the first direction.

When viewed in the first direction, the nozzles 23-1, 23-2, 23-3, 23-4, 23-5 and 23-7 are located at different positions in the circumferential direction of the process chamber 8. The first positions LA (which are the positions of the supply holes 24 (LA) provided in each of the nozzles 23-1, 23-2, 23-3, 23-4, 23-5 and 23-7) include the (1-1)^{th} position LA1 and the (1-2)^{th} position LA2 which is different from the (1-1)^{th} position LA1 in the circumferential direction of the process chamber 8. According to the present embodiments, in the cleaning cycle of the second cleaning step, supplying the first gas from the (1-1)^{th} position LA1 while stopping the supply of the first gas from the (1-2)^{th} position LA2 and supplying the first gas from the (1-2)^{th} position LA2 while stopping the supply of the first gas from the (1-1)^{th} position LA1 may be alternately performed. When the first gas is alternately supplied from the (1-1)^{th} position LA1 and the (1-2)^{th} position LA2 as described above, it is possible to suppress a non-uniform (or uneven) distribution of the first gas in the process chamber 8.

The first cleaning step and the second cleaning step mentioned above may be performed as shown in the following modified examples. Even in such modified examples, it is possible to obtain substantially the same effects as in the embodiments mentioned above.

### Modified Example of First Cleaning Step

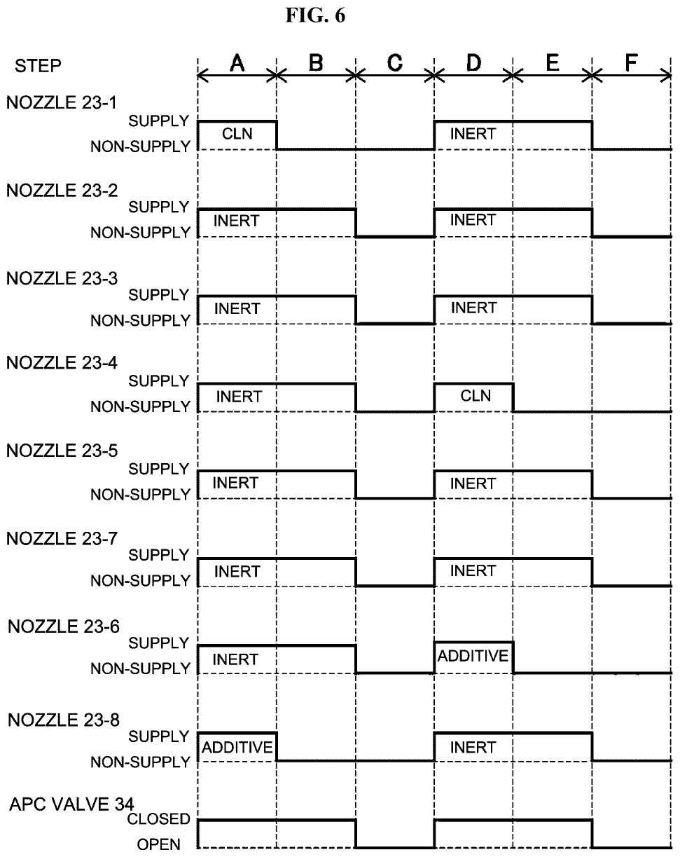

FIG. 6 is a timing chart schematically illustrating a modified example of the first cleaning step. In addition to the nozzles 23-1 to 23-7, in the modified example of the first cleaning step, the nozzle 23-8 is also used. The first cleaning step of the present modified example is substantially the same as the first cleaning step of the embodiments mentioned above except for features specifically mentioned below.

In the step A, the APC valve 34 is closed. Then, the cleaning gas serving as the first gas is supplied into the process chamber 8 through the nozzle 23-1. In addition, the additive gas serving as the second gas is supplied into the process chamber 8 through the nozzle 23-8. Further, the inert gas is supplied into the process chamber 8 through the nozzles 23-2, 23-3, 23-4, 23-5, 23-6 and 23-7. As a result, in the present step, similar to the step A of the first cleaning step in the embodiments mentioned above, the deposit in the process chamber 8 is removed. In the present modified example, similar to the embodiments mentioned above, the additive gas may be used as the first gas and the cleaning gas may be used as the second gas.

In the step B, the supply of the cleaning gas through the nozzle 23-1 is stopped and the supply of the additive gas through the nozzles 23-8 is also stopped. The inert gas is continuously supplied into the process chamber 8 through the nozzles 23-2, 23-3, 23-4, 23-5, 23-6 and 23-7. As a result, similar to the step A, the etching reaction mentioned above proceeds in the process chamber 8.

In the step C, the supply of the inert gas through the nozzles 23-2, 23-3, 23-4, 23-5, 23-6 and 23-7 is stopped. That is, in the step C, the supplies of the gases through the entirety of the nozzles 23 are stopped. Then, the APC valve 34 is opened. As a result, the exhaust gas after the deposit is removed is exhausted to the outside of the process chamber 8 through the exhaust pipe 32.

In the step D, the APC valve 34 is closed. Then, the cleaning gas serving as the first gas is supplied into the process chamber 8 through the nozzle 23-4. In addition, the additive gas serving as the second gas is supplied into the process chamber 8 through the nozzle 23-6. Further, the inert gas is supplied into the process chamber 8 through the nozzles 23-1, 23-2, 23-3, 23-5, 23-7 and 23-8. As a result, in the present step, similar to the step A of the present modified example, the deposit in the process chamber 8 is further removed.

In the step E, the supply of the cleaning gas through the nozzle 23-4 is stopped, and the supply of the additive gas through the nozzle 23-6 is also stopped. The inert gas is continuously supplied into the process chamber 8 through the nozzles 23-1, 23-2, 23-3, 23-5, 23-7 and 23-8. As a result, in the present step, similar to the step B of the present modified example, the deposit in the process chamber 8 is further removed.

In the step F, the supply of the inert gas through the nozzles 23-1, 23-2, 23-3, 23-5, 23-7 and 23-8 is stopped. In other words, in the step F, the supplies of the gases through the entirety of the nozzles 23 are stopped. Then, the APC valve 34 is opened. As a result, the exhaust gas after the deposit is removed is exhausted to the outside of the process chamber 8 through the exhaust pipe 32.

In the present modified example, the supply holes 24 (LA) of the nozzles 23-1 and 23-4 through which the cleaning gas is supplied are at the first positions LA which is located in the substrate placement region EA. In contrast, the supply holes 24 (LB) of the nozzles 23-6 and 23-8 through which the additive gas is supplied are at the second positions LB which is located in the substrate non-placement region EB. In addition, a pair of the nozzles 23-1 and 23-8 and a pair of the nozzles 23-4 and 23-6 are located at positions facing each other via the central axis CA. In other words, according to the present modified example, a distance between a supply position of the cleaning gas serving as the first gas and a supply position of the additive gas serving as the second gas is even greater than in the first cleaning step of the embodiments mentioned above. Therefore, it is possible to further suppress the deviations in the spatial concentration and the partial pressure of the halogen-containing active species generated by the etching reaction in the process chamber 8, and it is also possible to further suppress the local deviation in the etching amount in the process chamber 8.

According to the present modified example, the supply hole 24 (LA) is at the first position LA, and the cleaning gas serving as the first gas is supplied into the process chamber 8 from a plurality of long nozzles provided at different positions in the inner circumferential direction of the process chamber 8. In addition, the supply hole 24 (LB) is at the second position, and the additive gas serving as the second gas is supplied into the process chamber 8 from a plurality of short nozzles provided at different positions in the inner circumferential direction of the process chamber 8. In addition, a cycle including such steps is performed a predetermined number of times. Since the first gas is alternately (or sequentially) supplied into the process chamber 8 from the plurality of long nozzles as described above, it is possible to suppress the non-uniform (or uneven) distribution of the first gas in the process chamber 8. In addition, since the second gas is alternately (or sequentially) supplied into the process chamber 8 from the plurality of short nozzles as described above, it is also possible to suppress a non-uniform (or uneven) distribution of the second gas in the process chamber 8.

In the modified example of the first cleaning step, the second gas may be simultaneously supplied through both of the nozzle 23-6 and the nozzle 23-8. In the example mentioned above, the additive gas is supplied through both of the nozzle 23-6 and the nozzle 23-8 in the steps A and D. However, when the supply of the additive gas through the nozzle 23-6 and the supply of the additive gas through the nozzle 23-8 are performed in such different steps, it is possible to generate an intended concentration distribution of an active gas in the process chamber 8. As a result, it is possible adjust the distribution of the etching amount.

In addition, in the modified example of the first cleaning step, for example, the cleaning gas may be supplied through the nozzle 23-5 instead of the nozzle 23-1, or through the nozzle 23-7 instead of the nozzle 23-4. However, when the supply position of the cleaning gas serving as the first gas and the supply position of the additive gas serving as the second gas are separated from each other, it is possible to suppress a local damage and an unevenness of the etching in the process chamber 8. From such a viewpoint, in the step A, it is preferable to supply the cleaning gas through the nozzle 23-1 (which is farther from the nozzle 23-8) than through the nozzle 23-5 (which is closer to the nozzle 23-8). In addition, from such a viewpoint, in the step D, it is preferable to supply the cleaning gas through the nozzle 23-4 (which is farther from the nozzle 23-6) than through the nozzle 23-7 (which is closer to the nozzle 23-6).

### Modified Example of Second Cleaning Step

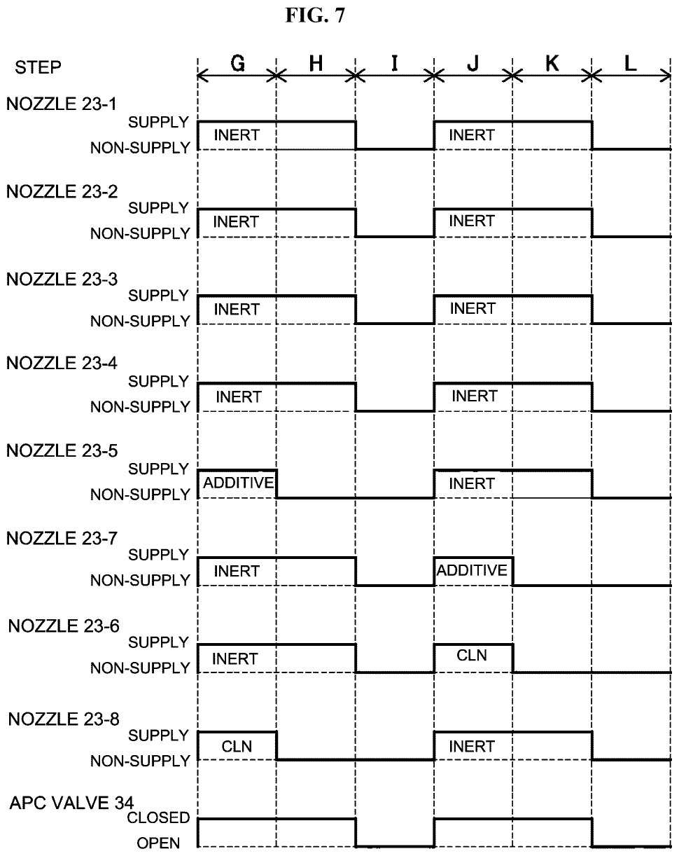

The second cleaning step mentioned above may be performed as shown in a modified example (that is, a modified example of the second cleaning step) in a timing chart shown in FIG. 7. In addition to the nozzles 23-1 to 23-7, in the modified example of the second cleaning step, the nozzle 23-8 is also used. The second cleaning step of the present modified example is substantially the same as the second cleaning step of the embodiments mentioned above except for features specifically mentioned below.

In the step G, the APC valve 34 is closed. Then, the cleaning gas serving as the first gas is supplied into the process chamber 8 through the nozzle 23-8. In addition, the additive gas serving as the second gas is supplied into the process chamber 8 through the nozzle 23-5. Further, the inert gas is supplied into the process chamber 8 through the nozzles 23-1, 23-2, 23-3, 23-4, 23-6 and 23-7. As a result, in the present step, similar to the step G of the second cleaning step in the embodiments mentioned above, the deposit in the process chamber 8 is removed.

In the step H, the supply of the cleaning gas through the nozzle 23-8 is stopped, and the supply of the additive gas through the nozzle 23-5 is also stopped. The inert gas is continuously supplied into the process chamber 8 through the nozzles 23-1, 23-2, 23-3, 23-4, 23-6 and 23-7. As a result, in the present step, similar to the step H of the second cleaning step in the embodiments mentioned above, the deposit in the process chamber 8 is removed.

In the step I, the supplies of the gases through the entirety of the nozzles 23 are stopped. Then, the APC valve 34 is opened. As a result, the exhaust gas after the deposit is removed is exhausted to the outside of the process chamber 8 through the exhaust pipe 32.

In the step J, the APC valve 34 is closed. Then, the cleaning gas serving as the first gas is supplied into the process chamber 8 through the nozzle 23-6. In addition, the additive gas serving as the second gas is supplied into the process chamber 8 through the nozzle 23-7. The inert gas is supplied into the process chamber 8 through the nozzles 23-1, 23-2, 23-3, 23-4, 23-5 and 23-8. Similar to the step G of the present modified example, the process chamber 8 is in a state where the cleaning gas and the additive gas are present, and the etching reaction occurs.

In the step K, similar to the step H, the supply of the cleaning gas through the nozzle 23-6 is stopped, and the supply of the additive gas through the nozzle 23-7 is also stopped. The inert gas is continuously supplied into the process chamber 8 through the nozzles 23-1, 23-2, 23-3, 23-4, 23-5 and 23-8. As a result, in the present step, similar to the step H of the present modified example, the deposit in the process chamber 8 is removed.

In the step L, similar to the step I, the supplies of the gases through the entirety of the nozzles 23 are stopped. Then, the APC valve 34 is opened. As a result, the exhaust gas after the deposit is removed is exhausted to the outside of the process chamber 8 through the exhaust pipe 32.

According to the present modified example, the distance between the supply position of the cleaning gas serving as the first gas and the supply position of the additive gas serving as the second gas in each execution of the cycle is even greater than in the second cleaning step of the embodiments mentioned above. Therefore, it is possible to further suppress the deviations in the spatial concentration and the partial pressure of the halogen-containing active species generated by the etching reaction in the process chamber 8, and it is also possible to further suppress the local deviation in the etching amount in the process chamber 8.

In the present modified example of the second cleaning step, the first gas may be supplied simultaneously through the nozzle 23-6 and nozzle 23-8. In the example mentioned above, the cleaning gas is supplied through both of the nozzle 23-6 and the nozzle 23-8 in the steps G and J. However, when the supply of the cleaning gas through the nozzle 23-6 and the supply of the cleaning gas through the nozzle 23-8 are performed in such different steps, it is possible to generate the intended concentration distribution of the active gas in the process chamber 8. As a result, it is possible adjust the distribution of the etching amount.

In addition, in the modified example of the second cleaning step, for example, the additive gas may be supplied through the nozzle 23-1 instead of the nozzle 23-5, or through the nozzle 23-4 instead of the nozzle 23-7.

In the modified example of the first cleaning step and the modified example of the second cleaning step, in addition to the nozzle 23-6, the nozzle 23-8 is used. The (2-1)^{th} position LB1 (which is the position of the supply hole 24 (LB) provided in the nozzle 23-6) and the (2-2)^{th} position LB2 (which is the position of the supply hole 24 (LB) provided in the nozzle 23-8) are different positions in the circumferential direction of the process chamber 8. Therefore, it is possible to supply the second gas in a dispersed manner into the process chamber 8 from different positions in the circumferential direction of the process chamber 8.

In the modified example of the first cleaning step and the modified example of the second cleaning step, the flow rate of the second gas supplied from the (2-1)^{th} position LB1 and the flow rate of the second gas supplied from the (2-2)^{th} position LB2 may be the same or different. However, by setting the flow rate of the second gas different between the (2-1)^{th} position LB1 and the (2-2)^{th} position LB2, it is possible to adjust the distribution of the second gas in the process chamber 8.

### Other Embodiments of the Present Disclosure

The technique of the present disclosure is described in detail by way of the embodiments mentioned above. However, the technique of the present disclosure is not limited thereto, and may be modified in various ways without departing from the scope thereof. The technique of the present disclosure may be applied when a so-called “straight nozzle” (also referred to as an “I-type nozzle”) is used as the nozzle 23. However, the technique of the present disclosure is not limited thereto. For example, the technique of the present disclosure may be applied to a nozzle such as a U-turn nozzle, a Y-type nozzle, an N-type nozzle or a W-type nozzle.

The substrate processing apparatus 1 according to the present embodiments can be applied not only to a semiconductor manufacturing apparatus but also to an apparatus capable of processing a glass substrate such as a liquid crystal display (LCD) device. In addition, for example, the film forming process may include a process such as a CVD (chemical vapor deposition) process, a PVD (physical vapor deposition) process, a process of forming an oxide film, a nitride film or both, and a process of forming a film containing a metal. In addition, the film forming process may further include a process such as an annealing process, an oxidation process, a nitridation process and a diffusion process.

The recipe used in the substrate processing apparatus 1 mentioned above is not limited to creating a new recipe. For example, the recipe may be prepared by changing an existing recipe stored (or installed) in the substrate processing apparatus 1 in advance. When changing the existing recipe to a new recipe, the new recipe may be installed in the substrate processing apparatus 1 via the electric communication line or a recording medium in which the new recipe is stored. Further, the existing recipe already stored in the substrate processing apparatus 1 may be directly changed to the new recipe by operating the input/output device 37 of the substrate processing apparatus 1.

For example, the embodiments mentioned above are described by way of an example in which a batch type substrate processing apparatus (that is, the substrate processing apparatus 1) capable of simultaneously processing a plurality of substrates is used form the film. However, the technique of the present disclosure is not limited thereto. For example, the technique of the present disclosure may be preferably applied when a single wafer type substrate processing apparatus capable of processing one or several substrates at a time is used to form the film. For example, the embodiments mentioned above are described by way of an example in which the substrate processing apparatus 1 including a hot wall type process furnace is used to form the film. However, the technique of the present disclosure is not limited thereto. For example, the technique of the present disclosure may be preferably applied when a substrate processing apparatus including a cold wall type process furnace is used to form the film.

Process procedures and process conditions of each process using the substrate processing apparatuses exemplified above may be substantially the same as those of the embodiments or the modified examples mentioned above. Even in such a case, it is possible to obtain substantially the same effects as in the embodiments or the modified examples mentioned above.

In addition, the embodiments and the modified examples mentioned above may be appropriately combined. The process procedures and the process conditions of each combination thereof may be substantially the same as those of the embodiments or the modified examples mentioned above.

As described above, according to some embodiments of the present disclosure, it is possible to suppress the deviation in the etching amount in the process chamber.

What is claimed is:

1. A cleaning method comprising:
(a) supplying a first gas into a process chamber from one or more first positions in a first direction; and
(b) supplying a second gas into the process chamber from one or more second positions in the first direction different from the one or more first positions,
wherein the process chamber is configured to be capable of accommodating a substrate along a plane perpendicular to the first direction,
the first gas is one of a cleaning gas and an additive gas reacting with the cleaning gas, and
the second gas is the other one of the cleaning gas and the additive gas.

2. The cleaning method of claim 1, wherein the process chamber is surrounded by a process vessel provided with an opening at a lower end thereof in the first direction and a lid capable of closing the opening, and
wherein the one or more second positions are located closer to the lower end in the first direction than the one or more first positions.

3. The cleaning method of claim 1, wherein the process chamber is provided with a substrate placement region arranged along the first direction in which the substrate is placed and a substrate non-placement region arranged along the first direction in which the substrate is not placed, and
wherein the one or more first positions are located where the substrate placement region is arranged in the first direction, and the one or more second positions are located where the substrate non-placement region is arranged in the first direction.

4. The cleaning method of claim 1, wherein the process chamber is configured to accommodate a substrate support capable of supporting the substrate in the process chamber, and
wherein (a) and (b) are performed while the substrate support is accommodated in the process chamber.

5. The cleaning method of claim 4, wherein the substrate support is constituted by a substrate support structure configured to support the substrate and a heat insulator located at a position different from that of the substrate support structure in the first direction,
wherein the one or more first positions are located where the substrate support structure is provided in the first direction, and the one or more second positions are located where the heat insulator is provided the first direction.

6. The cleaning method of claim 1, wherein a first nozzle extending in the first direction is provided in the process chamber and is provided with one or more first supply holes; and
wherein the one or more first positions are set as one or more positions of the one or more first supply holes.

7. The cleaning method of claim 6, wherein a plurality of first supply holes are provided in the first nozzle along the first direction as the one or more first supply holes.

8. The cleaning method of claim 1, wherein (a) and (b) are performed so as to overlap with each other at least partially in time.

9. The cleaning method of claim 1, wherein (a) and (b) are performed in a state where an exhaust of the process chamber is stopped.

10. The cleaning method of claim 1, wherein (a) and (b) are performed such that the first gas and the second gas are mixed in the process chamber.

11. The cleaning method of claim 3, wherein the additive gas is supplied from the one or more first positions and the cleaning gas is supplied from the one or more second positions.

12. The cleaning method of claim 1, further comprising
(c) after (a) and (b), exhausting the first gas and the second gas from the process chamber in a state where a supply of the first gas and a supply of the second gas are stopped, and
wherein a cleaning cycle comprising (a), (b) and (c) is performed a plurality number of times.

13. The cleaning method of claim 1, wherein at least one among the one or more first positions and at least one among the one or more second positions are located at positions facing each other via a central axis of the process chamber extending in the first direction.

14. The cleaning method of claim 1, wherein the one or more second positions comprise a (2-1)^{th} position and a (2-2)^{th} position different from the (2-1)^{th} position along a circumferential direction of the process chamber.

15. The cleaning method of claim 14, wherein a plurality of cleaning cycles, each cycle of which comprise (a) and (b), are performed,
wherein the plurality of cleaning cycles comprise a cycle in which the second gas is supplied from the (2-1)^{th} position while stopping a supply of the second gas from the (2-2)^{th} position, and
wherein the plurality of cleaning cycles further comprise a cycle in which the second gas is supplied from the (2-2)^{th} position while stopping the supply of the second gas from the (2-1)^{th} position.

16. The cleaning method of claim 15, wherein the one or more first positions comprise a (1-1)^{th} position and a (1-2)^{th} position different from the (1-1)^{th} position along the circumferential direction of the process chamber,
wherein the plurality of cleaning cycles comprise a cycle in which the first gas is supplied from the (1-1)^{th} position while stopping a supply of the first gas from the (1-2)^{th} position, and
wherein the plurality of cleaning cycles further comprise a cycle in which the first gas is supplied the (1-2)^{th} position while stopping the supply of the first gas from the (1-1)^{th} position.

17. The cleaning method of claim 16, wherein the (1-1)^{th} position and the (2-1)^{th} position are located at positions facing each other via a central axis of the process chamber extending in the first direction, and the (1-2)^{th} position and the (2-2)^{th} position are located at positions facing each other via the central axis.

18. A method of manufacturing a semiconductor device, comprising:
the method of claim 1.

19. A non-transitory computer-readable recording medium storing a program that causes a substrate processing apparatus, by a computer, to perform:
(a) supplying a first gas into a process chamber from one or more first positions in a first direction; and
(b) supplying a second gas into the process chamber from one or more second positions in the first direction different from the one or more first positions,
wherein the process chamber is configured to be capable of accommodating a substrate along a plane perpendicular to the first direction,
the first gas is one of a cleaning gas and an additive gas reacting with the cleaning gas, and
the second gas is the other one of the cleaning gas and the additive gas.

20. A substrate processing apparatus comprising:
a process chamber configured to be capable of accommodating a substrate along a plane perpendicular to a first direction;
a first gas supplier configured to supply a first gas into the process chamber through one or more first supply holes provided at one or more first positions in the first direction;
a second gas supplier configured to supply a second gas into the process chamber through one or more second supply holes provided at one or more second positions in the first direction different from the one or more first positions; and
a controller configured to be capable of controlling the first gas supplier and the second gas supplier to supply the first gas and the second gas into the process chamber,
wherein the first gas is one of a cleaning gas and an additive gas reacting with the cleaning gas, and
the second gas is the other one of the cleaning gas and the additive gas.
